(19) United States
(12) Patent Application Publication
(10) Pub. No.: US 2013/0026760 A1
(43) Pub. Date: Jan. 31, 2013

(54) METHOD FOR TREATING ORGANIC WASTE AND METHOD AND APPARATUS FOR PRODUCING SOLID FUEL/COMPOST USING ZERO DISCHARGE ACE SYSTEM

(71) Applicants: Haeng Seog Lee, Seoul (KR); Eun Min Cho, Seoul (KR); Han Jun Lee, Seoul (KR)

(72) Inventors: Haeng Seog Lee, Seoul (KR); Eun Min Cho, Seoul (KR); Han Jun Lee, Seoul (KR)

(73) Assignee: NEW & RENEWABLE ENERGY CO., LTD., Gyeonggi-do (KR)

(21) Appl. No.: 13/559,970

(22) Filed: Jul. 27, 2012

(30) Foreign Application Priority Data
Jul. 29, 2011 (KR) 10-2011-0075850

(51) Int. Cl. C02F 3/00; F01D 15/10; C10L 5/40; C02F 3/02; H01L 35/30

(52) U.S. Cl. 290/52; 210/609; 210/151; 136/205; 44/589

(57) ABSTRACT

The present invention relates to a method and apparatus for treating organic waste and producing solid fuel or compost from the treated organic waste.

### CROSS-REFERENCE TO RELATED APPLICATION

This application claims priority to and the benefit of Korean Patent Application No. 2011-0075850, filed on Jul. 29, 2011, the disclosure of which is incorporated herein by reference in its entirety.

### BACKGROUND OF THE INVENTION

1. Field of the Invention

The present invention relates to a composite system providing a method and apparatus for treating organic waste (including food waste, livestock excretion, or sludge) and producing solid fuel or compost from the organic waste, and more particularly to a method for treating organic waste without separation of the organic waste into solid and liquid wastes, or a method for separating organic waste into solid and liquid wastes, reducing the weight of the solid waste, and treating the liquid waste with water and organic matter necessary for microorganisms during the treatment, in contrast to the conventional water treatment method that entails production of discharge water. The present invention also relates to a method for treating food waste, livestock excretion, or sludge with a zero discharge ACE system using fermentation microorganisms and a composite system providing a method and apparatus for producing compost/solid fuel using the treatment method, where the final product after treatment is converted into compost or solid fuel, and the organic waste is added to efficiently enhance the heating value of the solid fuel, thereby producing solid fuel with high heating value and avoiding production of discharge water.

2. Background Art

Food waste as a kind of organic waste refers to food discarded uneaten from houses, restaurants, food factories, and so forth and has taken a significant ratio in the household waste with the enhanced quality of human life.

Food waste consists of 30% of solid waste and 70% of liquid waste. Particularly, the liquid waste has a high level of contamination, such as high concentration of organic matter amounting to 200,000 ppm/BOD, and is difficult to dispose without being diluted with water 20 to 50 times greater in volume, requiring treatment facilities in greater scale and higher costs for facilities, so more than a half the liquid waste is being dumped into the sea. As the quantity of liquid waste dumped into the sea amounts to about 5,000 m³/day, sea dumping is going to be prohibited from 2012 according to the London Dumping Convention against environmental pollutions. But, there is an urgent demand for treatment methods in response to the sea dumping prohibition. The conventional treatment techniques for liquid waste produced from food waste involve a water treatment combining physical, chemical and biological methods together, with difficulty in meeting the quality standard for discharge water and problem in association with environment-related facilities such as a water disposal system.

Livestock excrement (liquid phase) among the organic wastes is treated by incineration, drying, or anaerobic digestion in addition to the aforementioned treatment techniques of the liquid food waste. The anaerobic digestion method is to treat waste water using anaerobic microorganisms, which requires blocking from oxygen, resulting in strict operational conditions, long processing time, and high costs for disposal facilities.

Organic waste, such as livestock excretion or food waste, is difficult to evaporate by incineration method due to its high moisture content and likely to cause water contamination with waste water when discharged without proper treatment or dumped into the sea, or bring about soil and water contamination with leachate generated by landfill.

Sludge refers to the residual left from the liquid generated by disposal of sewer water or waste water and has been increased in quantity with sustained increase in the number of disposal facilities for sewer and waste water in association with industrial development. Due to its high moisture content of about to 80%, there are concerns about sludge disposal in a landfill, such as reducing the life of landfill facilities, generating foul odor and leachate with increased concentration, causing contamination of soil and ground water around the landfill, and raising the disposal cost due to excessively high costs for leachate disposal facility and maintenance. Further, such a high moisture content of sludge lowers the heating value during incineration, increasing consumption of auxiliary fuel, and causes generation of air pollutants such as dioxin, which results from chlorinated compounds and low incineration temperature.

The inventors of the present invention have been studying on a method for reducing the weight of sewer sludge and organic waste alone or in combination using a microorganism formulation and then producing solid fuel having a high heating value and recognized some problems with the method, such as generating a large quantity of liquid waste during pulverization or dehydration of the food waste and having difficulty in livestock urine disposal. Furthermore, the conventional method requires a separate water treatment apparatus for liquid waste disposal. Thus there is an urgent demand for a new treatment method that is capable of dramatically solving the problems with the prior art. In other words, such a novel treatment method for organic waste is required to dispose organic waste with simple operational conditions, low cost for disposal facility and short processing time, and to convert the organic waste into bio-resource or energy, with no need for a discharge of liquid waste generated by organic waste treatment, in contrast to the conventional water treatment method which entails a discharge of liquid waste.

### SUMMARY OF THE INVENTION

To solve the problems with the prior art, it is an object of the present invention to provide a method for treating organic waste, such as livestock excretions, sludge (including concentrated raw sludge, excess sludge, or dewatered cake) with microorganisms without separating organic waste into solid and liquid wastes, and a process for separating food waste by pulverization, treating the solid waste with microorganisms in a fermentation tank, and adding the liquid waste into the fermentation tank as a supply of water and organic matters necessary for the microorganisms to decompose the organic matter in the liquid waste. The heat generated by this process is used to evaporate water from the organic waste, and the final product (i.e., humus) is produced as compost. Further, a part of the organic matter remaining in the organic waste is used in production of solid fuel having a high heating value. In other words, the present invention is directed to a system for providing a method for treating organic waste, and a method and apparatus for producing solid fuel or compost with a zero discharge ACE system using a microorganism formulation.

It is another object of the present invention to provide a zero discharge ACE system using a microorganism formulation that provides a method for treating organic waste and a method for producing solid fuel, where the organic waste for production of solid fuel is dried through an exothermic reaction (at 75 C or above) using the energy generated from decomposition of organic matter included in the organic waste by microorganisms rather than using external energy such as electricity or fuel oil, to minimize the use of external energy (e.g., fossil fuels, such as bunker C oil or gas oil, and electricity) as an energy supplement in the production of solid fuel. Thus, the present invention is to produce solid fuel with organic waste only, thereby minimizing environmental pollution caused by treatment of organic waste and contributing to reduction of the cost for treatment of organic waste and recycling of waste into energy.

It is a still another object of the present invention to provide a system providing a method for treating organic waste, and a method and apparatus for producing solid fuel using a zero discharge ACE system, in which the waste heat generated in the drying process to produce solid fuel from the organic waste is used to convert thermal energy into electrical energy with thermoelectric elements, or the high-speed steam flow generated from combustion of solid fuel in a solid fuel boiler is used to convert mechanical energy into electrical energy through a combined heat-and-power generator.

To achieve the objects of the present invention, there is provided a method for treating organic waste with a zero discharge ACE system using a microorganism formulation that comprises:

a storing step for adding and storing organic waste in a storage hopper and transferring a naturally occurring liquid waste to a liquid waste storage tank, where the organic waste is food waste;

a pulverization and separation step for transferring the food waste of the storing step to a pulverizing separator to pulverize the food waste, blowing off light-weighted substances, such as vinyl, etc., with a turbulent flow caused by a wind force and separating the food waste from heavy-weighted foreign substances including bones or stones;

a compress dehydration step for separating the pulverized food waste of the pulverizing separator into a solid waste and a liquid waste using a dehydrator (or by natural separation without using a dehydrator) and then transferring the solid waste to a mixing tank and the liquid waste to the liquid waste storage tank;

a mixing step for mixing the separated solid waste of the compress dehydration step with a bulking agent, such as woodchip or sawdust, and adding microorganisms (or a returned microorganism formulation) to the mixture; or mixing the organic waste comprising livestock excretion or sludge in the form of slurry with flammable industrial waste (e.g., woodchip or sawdust) as a bulking agent and adding microorganisms (or a returned microorganism formulation) to the mixture;

a pre-fermentation step for transferring the organic waste (including the bulking agent and the microorganisms) of the mixing step to a pre-fermentation tank to accelerate a microorganism fermentation reaction;

a fermentation step for removing water from the organic waste of the pre-fermentation step using a heat generated while the microorganisms decompose the organic matter of the organic waste, adding the liquid waste of the liquid waste storage tank to food waste as the organic waste during fermentation (alternatively, adding excretion slurry when the organic waste is livestock excretion, or concentrated raw sludge when the organic waste is sewer sludge), and injecting an appropriate amount of air to remove water from the liquid waste (or slurry or raw sludge) using the heat energy generated by catabolism of the organic matter included in the liquid waste (or slurry or raw sludge) and reduce the final moisture content of the solid waste to 55% or less;

a post-fermentation step for adding an appropriate amount of the liquid waste of the liquid waste storage tank at the rear end of the fermentation tank after the fermentation step to partly restrain decomposition of the organic matter included in the liquid waste (or slurry for livestock excretion) using fermentation microorganisms, and removing water from the liquid waste using a heat generated from decomposition of the organic matter to raise a heating value of the solid fuel which is produced from the remaining organic matter subsequently;

a separation and feedback step for separating woodchip from a humus of the organic waste of the post-fermentation step with a drum screen separator and feeding the isolated woodchip or sawdust and a part of the humus of the organic waste back to the mixing tank;

a packaging step for transferring the remaining humus from the separation and feedback step to a composting tank for making compost for a predetermined period of time, and transferring the compost to a packaging unit to produce a compost product;

a pulverizing step for pulverizing the remaining humus from the separation and feedback step into particles having a size of mm or smaller with a roll crusher to produce a solid fuel having a uniform heating value;

a drying step for drying the crushed humus of the pulverization step to have a moisture content of 20% or less using a hot air boiler at 200 C or below (in a temperature range not allowing volatilization of the organic matter) in order to remove the remaining water from the crushed humus;

a press molding step for press-molding the dried humus of the drying step into pellets in order to produce a solid fuel; and

a packaging step for transferring a part of the solid fuel produced in the press molding step to the hot air boiler for solid fuel for use as a source of heat, and a remainder of the solid fuel to the packaging unit to form the final solid fuel product.

In the method for treating organic waste (including food waste, livestock excretion, or sludge) according to the present invention, the foul odor such as ammonia nitrogen and the waste heat generated from the drying step are transferred to the fermentation tank, which eliminates the foul odor using microorganisms and uses the waste heat in evaporation of water.

The method of the present invention further comprises a method for converting a waste heat generated from the hot air boiler used in the drying step into electrical energy using thermoelectric elements, and a method for combusting the solid fuel product in a dedicated boiler for solid fuel and using the high-speed steam flow generated from the combustion to convert mechanical energy into electrical energy with a combined heat-and-power generator.

According to the present invention, the liquid waste (or slurry of livestock excretions, and concentrated raw sludge of sewer sludge) generated in the process of pulverizing and dehydrating food waste is not subjected to the conventional water treatment method but added to a fermentation step for treating a solid waste mixed with woodchip and sawdust, to decompose high-concentration organic matters of the liquid waste using microorganisms and use the heat generated from an exothermic reaction (catabolism) during decomposition of the organic matters in removing water from the liquid waste, thereby providing a way of treating the organic waste without discharging the liquid waste.

In the method for producing a solid fuel from organic waste according to the present invention, the heat generated when microorganisms decompose organic matters included in the organic waste is used to continuously remove water, thereby providing a solid fuel generated from the organic waste at low cost and actively preventing environmental pollution caused by organic wastes.

According to the present invention, instead of using inorganic heat supplements, such as anthracite, cork, oil, etc., the organic matters of organic waste and flammable industrial wastes, such as woodchip or sawdust, are used to produce a solid fuel, thus reducing the production cost of a solid fuel and preventing occurrence of secondary environmental contaminants during combustion of the solid fuel. Further, liquid food wastes or slurry of livestock excretions is added to increase the concentration of the organic matter, or a fatty liquid waste having a high heating value among the liquid wastes is added in the post-fermentation process to produce a solid fuel having a high heating value.

The present invention also produces compost or a solid fuel from a humus formed after treatment of organic wastes using a microorganism formulation and generates energy by converting heat energy into electrical energy from the heat generated in the drying process for the solid fuel with thermoelectric elements using a waste or with a combined heat-and-power generator using a dedicated boiler for combustion of solid fuel.

### BRIEF DESCRIPTION OF THE DRAWINGS

FIG. 1 is a schematic flow diagram showing a method for treating organic waste and a method for producing a solid fuel based on a zero discharge ACE system using a microorganism formulation according to the present invention.

FIG. 2 is a schematic flow diagram showing a method for treating organic waste and a method for producing a solid fuel based on a zero discharge ACE system using a microorganism formulation according to the present invention.

FIG. 3 is a schematic flow diagram showing a method for treating organic waste and a method for producing a solid fuel based on a zero discharge ACE system using a microorganism formulation according to the present invention (W: organic waste; L: liquid waste; S: solid waste; P: solid fuel; H: humus; O: microorganisms and C: woodchip or sawdust).

FIG. 4 is a schematic block diagram showing an electrical generator according to the present invention.

FIG. 5 is a graph showing the quantity of food waste treated with a microorganism formulation according to the present invention.

FIG. 6 is a graph showing the quantity of livestock excretion treated with a microorganism formulation according to the present invention.

FIG. 7 is a drawing showing the change of temperature pertaining to the batch reaction of food waste using a microorganism formulation according to the present invention.

FIG. 8 is a graph showing the quantity of livestock excretion treated with a microorganism formulation according to the present invention.

FIG. 9 is a graph showing the quantity of livestock excretion continuously treated with a microorganism formulation according to the present invention.

### DETAILED DESCRIPTION OF THE PREFERRED EMBODIMENT

Hereinafter, a description will be given as to a method for treating organic waste and a method and apparatus for producing solid fuel or compost based on a zero discharge ACE system using a microorganism formulation according to the present invention with reference to the accompanying drawings.

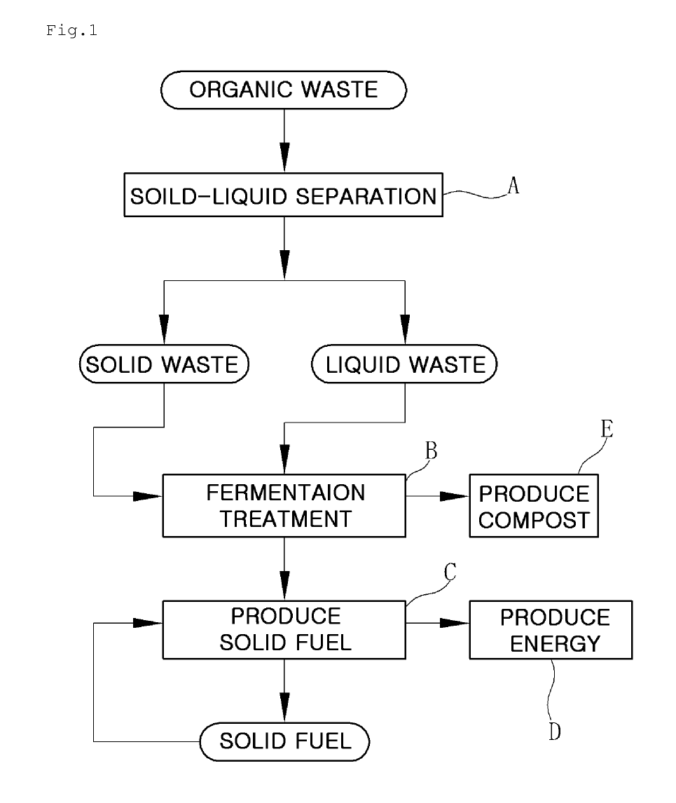

As shown in FIG. 1, the a method for treating organic waste and a method and apparatus for producing solid fuel or compost based on a zero discharge ACE system using a microorganism formulation according to the present invention comprise: a solid-liquid separation step (A) for separating a mixed organic waste consisting of liquid and solid wastes into liquid and solid wastes; and a fermentation step (B) for adding a liquid food waste or a liquid waste (including urine and cleaning water) of livestock excretions as separated in the solid-liquid separation step (A) during fermentation and decomposition of the solid waste of the solid-liquid separation step (A) and using a heat generated by decomposition of organic matter included in the liquid waste to remove water from the liquid waste.

The present invention further comprises: a solid fuel production step (C) for producing a solid fuel from the solid waste removed of water in the fermentation step (B); a composing step (E) for producing compost from the solid waste; and an energy production step (D) for producing energy using a waste heat generated in the solid fuel production step (C).

When the organic waste is food waste having a high moisture content, the treatment of the food waste without pulverization may deteriorate the treatment efficiency because it takes time for the microorganisms to destroy the cell membranes of the food waste. Accordingly, the present invention involves separating food waste into a solid waste and a liquid waste (or treating food waste without the separation process), adding microorganisms or a bulking agent to the solid waste having an appropriate moisture content to induce a fermentation reaction using microorganisms and remove organic matter and water from the solid waste, and then adding an appropriate amount of the liquid waste continuously or at predetermined time intervals in order to supply water necessary to the microorganisms of the fermentation step to decompose the organic matter included in the liquid waste and remove water from the liquid waste using a heat generated by the decomposition of the organic matter, thereby eliminating all the liquid waste occurring during the treatment of food waste or the liquid waste of livestock excretions to prevent a discharge of the liquid waste. The organic waste, such as livestock excretions or sewer sludge, skips the solid-liquid separation step and directly goes to the fermentation step.

To raise the heating value of the solid fuel, the present invention involves adding an appropriate amount of the liquid waste (or slurry of livestock excretions) at the rear end of the fermentation tank, decomposing the organic matter included in the liquid waste using microorganisms, removing water from the liquid waste using a heat generated during the decomposition of the organic matter, and producing a solid fuel having a high heating value from the remainder of the organic matter, thereby preventing a discharge of the liquid waste occurring in the process of organic waste treatment.

In contrast to the conventional organic waste treatment method which demands sea dumping of the organic waste or using a separate water treatment facility, resulting in the complicated construction of the apparatus, the present invention adds a liquid waste (or slurry of livestock excretions) and a solid waste in the step of solid fuel production and uses a heat generated from microorganism fermentation reaction to completely remove water from the liquid waste, making the construction of the apparatus simple, solving the problems, such as discharge, sea dumping, or waste land fill, and also producing a solid fuel having a high heating value.

The method for treating organic waste and the method for producing a solid fuel according to the present invention according to the present invention have been described mainly in regard to the food waste but may also be applicable to other organic wastes, which include livestock excretions alone or in combination with food waste or sewer sludge, or food waste in combination with sewer sludge.

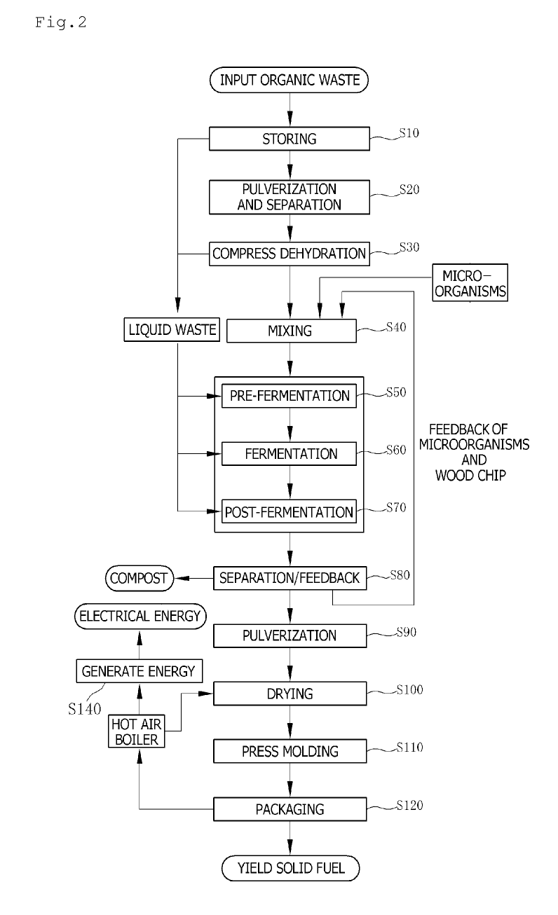

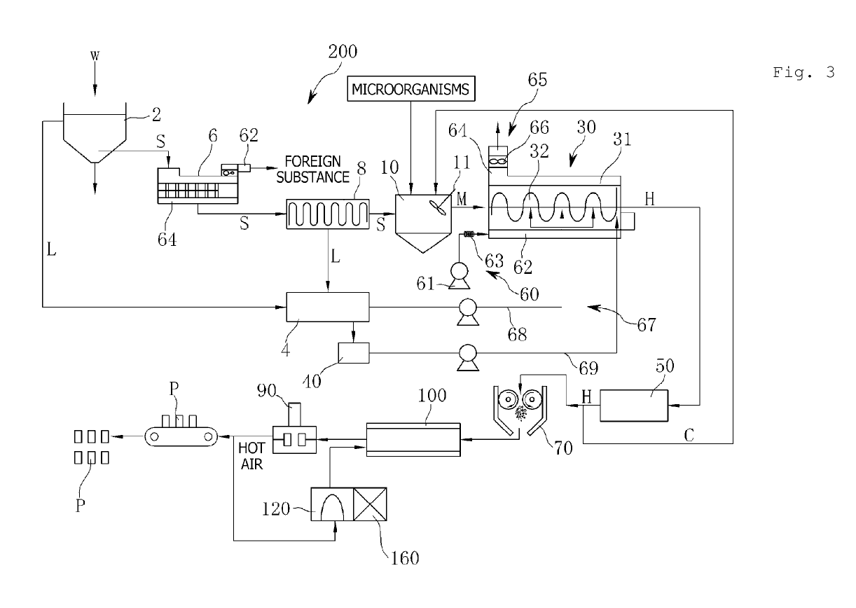

Referring to FIGS. 2 and 3, the method for treating organic waste and the method for producing compost/solid fuel based on a zero discharged ACE system using a microorganism formulation according to the present invention comprises:

a storing step S10 for adding and storing organic waste in a storage hopper 2 and transferring a naturally occurring liquid waste L to a liquid waste storage tank 4;

a pulverization and separation step S20 for transferring the organic waste of the storing step S10 to a pulverizing separator to pulverize the organic waste, blowing off light-weighted substances, such as vinyl, etc., with a turbulent flow caused by a wind force and separating the organic waste from heavy-weighted foreign substances including bones or stones;

a compress dehydration step S30 for separating the pulverized organic waste of the pulverization and separation step S20 into a solid waste S and a liquid waste L using a dehydrator 8 and then transferring the solid waste S to a mixing tank 10 and the liquid waste L to the liquid waste storage tank 4;

a mixing step S40 for mixing the separated solid waste L of the compress dehydration step S30 with a microorganism formulation (or a returned microorganism formulation, new sawdust, woodchip, or microorganisms);

a pre-fermentation step S50 for transferring the mixture of the microorganism formulation and the solid waste S (hereinafter, referred to as “mixture M”) of the mixing step S40 to a fermentation tank 30 and adding the liquid waste when needed to control the moisture content, to accelerate a microorganism fermentation reaction;

a fermentation step S60 for removing water from the solid waste S of the pre-fermentation step S50 using a heat generated from the decomposition of organic matter by fermentation microorganisms, adding the liquid waste L of the liquid waste storage tank 4 to an appropriate amount of the mixture M (including the solid waste and the microorganism formulation) for control of the moisture content for the fermentation microorganisms to decompose the organic matter included in the liquid waste L and remove water from the liquid waste L, thereby reducing the final moisture content of the solid waste 5 to 55% or less; and

a post-fermentation step S70 for adding an appropriate amount of the liquid waste L stored in the liquid waste storage tank 4 with respect to the mixture M at the rear end of the fermentation tank 30 after the fermentation step S60 to partly treat the organic matter and water included in the liquid waste L and also to raise a heating value of the solid fuel which is to be produced from the remaining organic matter subsequently.

As described above, the storing step S10, the pulverization and separation step S20, and the compress dehydration step S30 are a solid-liquid separation step A for separating the organic waste into a liquid waste L and a solid waste S. The solid-liquid separation step A is the process for separating an organic waste having an extremely high moisture content and difficult to treat with microorganisms into a solid waste S having an appropriate moisture content and a liquid waste L. In contrast to the prior art that decomposes food waste having a high moisture content in an anaerobic tank or separates food waste into solid and liquid wastes to treat the liquid waste in a separate water treatment facility, the present invention uses up the liquid waste L and the solid waste S in the process for producing a solid fuel P.

Subsequently, the mixing step S40, the pre-fermentation step S60, and the post-fermentation step S70 are a process for fermenting and decomposing the separated solid waste S of the solid-liquid separation step A using microorganisms. This is a fermentation step B for adding an appropriate amount of the separated liquid waste L in order to supply water necessary to the growth of the microorganisms in the fermentation process, and removing all the water from the liquid waste using a heat generated from the exothermic reaction by microorganisms. In other words, microorganisms are added to the solid waste S having an appropriate moisture content to induce a microorganism-driven fermentation reaction and remove the organic matter from the solid waste, and the heat thus generated is used to remove water from the solid waste S. To control the moisture content for microorganisms necessary to the fermentation process, an appropriate amount of the liquid waste L is added continuously or at predetermined time intervals to generate a heat from the exothermal reaction for decomposition of the organic matter included in the liquid waste L, and the heat thus generated is used to remove water from the liquid waste L.

Referring to FIGS. 2 and 3 again, the method for producing a solid fuel using a microorganism formulation according to the present invention comprises:

a separation and feedback step S80 for separating woodchip from a humus H of the organic waste of the post-fermentation step S70 with a drum screen separator 50 and feeding the isolated woodchip or sawdust and the humus of the organic waste (i.e., the returned microorganism formulation) back to the mixing tank 10 in an amount of about 30 wt % with respect to the mixture M;

a pulverizing step S90 for pulverizing the remaining humus H from the separation and feedback step S80 into particles having a size of 5 mm or smaller with a roll crusher 70 to produce a solid fuel having a uniform heating value;

a drying step S100 for drying the crushed humus H of the pulverization step S90 to have a moisture content of 20% or less using a hot air boiler 120 at 200 C or below (in a temperature range not allowing volatilization of the organic matter) in order to remove the remaining water from the crushed humus H;

a press molding step S110 for press-molding the dried humus H of the drying step S100 into pellets to produce a solid fuel P; and

a packaging step S120 for transferring a part of the pellets from the press molding step S110 to the hot air boiler 120 dedicated to the solid fuel for use as a source of heat, and a remainder of the solid fuel to a packaging unit 140 to form the final solid fuel product.

More specifically, the solid waste S used to remove the liquid waste becomes humus H removed of organic matters and water. The humus H is processed into a solid fuel P in the solid fuel production step C.

In particular, the present invention can use liquid food wastes containing lots of oils or fats in the post-fermentation step S70 to produce a solid fuel P having a high heating value. For this purpose, the liquid waste storage tank 4 is equipped with an oil-water separator 40 for separating oils or fats, and the separated oils or fats of the oil-water separator 40 are fed into the rear end of the fermentation tank 30.

On the other hand, the pulverization step S90 and the drying step S100 are not necessary when the humus H separated in the separation and feedback step S80 is used to make compost.

The present invention transfers a part of the dried solid fuel P to the hot air boiler 120 dedicated to the solid fuel and uses it as a source of heat to dry the solid fuel P, thereby minimizing consumption of external energy (fossil oils such as bunker C oil or gas oil).

The present invention further comprises an electricity generation step S140 for converting heat energy into electrical energy with thermoelectric elements using a waste heat generated from combustion of solid fuel in the hot air boiler 120 dedicated to solid fuel or with a combined heat-and-power generator using a dedicated boiler for combustion of solid fuel.

FIG. 3 is a block diagram showing an example of the apparatus for treating organic waste and producing solid fuel based on a zero discharge ACE system using a microorganism formulation according to the present invention.

As illustrated in FIG. 3, the apparatus for treating organic waste and producing compost/solid fuel based on a zero discharge ACE system using a microorganism formulation according to the present invention comprises a storage hopper 2, a liquid waste storage tank 4, a pulverizing separator 6, a dehydrator 8, a mixing tank 10, a fermentation tank 30, a drum separator 50, a roll crusher 70, a drying furnace 100, a molding unit 90, a hot air boiler 120, a packaging unit 140, and an electricity generator 160.

The storage hopper 2 is to store organic wastes (especially, food waste) and equipped with a connection pipe 24 provided on the one side of its bottom end and connected to the liquid waste storage tank 4 and a discharge pipe 21 provided its bottom end and used to discharge food waste. Thus, the liquid waste L naturally occurring from the food waste stored in the storage hopper 2 is transferred to the liquid waste storage tank 4.

The organic waste stored in the storage hopper 2 is transferred to the pulverizing separator 6. The pulverizing separator 6 includes an air blower 62 and a screen drum 65. Hence, light-weighted substances such as vinyl are blown off using turbulent flow caused by the wind force of the air blower 62, and heavy-weighted substances such as stones are separated from the organic waste through the screen drum 64.

The separated organic waste from the pulverizing separator 6 is sent to the dehydrator 8. The dehydrator 8 compresses the food waste into a solid waste S and a liquid waste L. The liquid waste L is sent to the liquid waste storage tank 4, and the solid waste S is sent to the mixing tank 10.

The mixing tank 10 has an agitator 11 to mix the solid waste S and the microorganism formulation together. A part of the microorganism formulation includes the returned humus, woodchip or sawdust separated from the drum separator 50, which is to be described below.

The mixture M of the mixing tank 10 is fed into the fermentation tank 30. The fermentation tank 30 comprises a cubic main body 31 having an inlet for the mixture M injected from the mixing tank 10 and an outlet for the humus H after completion of the fermentation step, and internally provided with an escalator type agitator 32 for continuously stirring the mixture M and continuously moving the mixture M from inlet to outlet; an air feeding device 60 for injecting air into the main body 31; an air discharging device 80 for outwardly discharging internally occurring water vapor; and a liquid waste feeding device 67 for injecting the liquid waste L into the main body 31.

The air feeding device 60 comprises an air feeding passage 62 provided around the air blower 61 and the main body 31 and guiding air to the outlet of the fermentation tank 30. The air discharging device 80 comprises an air vent 34 provided on the top of the main body 31, and a fan 66 provided in the air vent 34. The air feeding passage 62 is equipped with a heater 63 to warm the air fed into the main body 31.

The liquid waste feeding device 67 comprises a plurality of feeding pipes 68 and 69 connected to the liquid waste storage tank 4, each feeding pipe being provided with a separate pump and valves. Among the feeding pipes 68 and 69, a first feeding pipe 68 connected to the middle part of the fermentation tank 30 has its end provided with a nozzle for supply of the liquid waste L, and a second feeding pipe 69 connected to the rear end of the fermentation tank 30 is linked to the oil-water separator 40 to feed oils and fats in the liquid waste L.

The drum screen 50 separates woodchip or sawdust C with a rotary screen. The woodchip or sawdust C separated by the drum screen 50 and a part of the humus H of the organic waste are fed back to the mixing tank 10. The returned humus H and woodchip C take about 30 wt % of the mixture M.

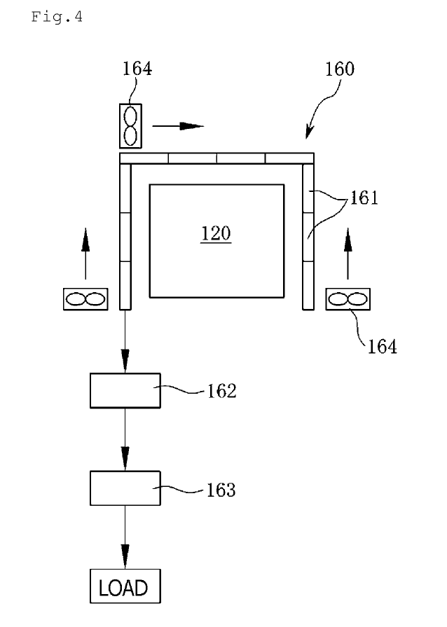

As shown in FIG. 4, the electricity generator 160 including a plurality of thermoelectric elements 161 is provided around the hot air boiler 120. The thermoelectric element 161 is a device for using the Seebeck effect which is the conversion of temperature differences into electromotive force, and producing electricity by the temperature difference between the side facing the hot air boiler 120 and the opposite side. On the opposite side to the side facing the hot air boiler 120 are provided a cooling pin for lowering the temperature and a plurality of air blowers 164 for circulating the external air. The thermoelectric elements 161 are connected to a plurality of capacitors 163 for storing the produced electrical energy through an inverter 162 for voltage control. The capacitors 163 are connected to the respective devices of the apparatus for treating organic waste and producing solid fuel according to the present invention to provide power supply.

Further, the high-speed steam flow generated from combustion of solid fuel at the boiler dedicated to the produced solid fuel can be used to rotate the turbine of a combined heat-and-power generator and convert mechanical energy into electrical energy.

<Experiment 1>

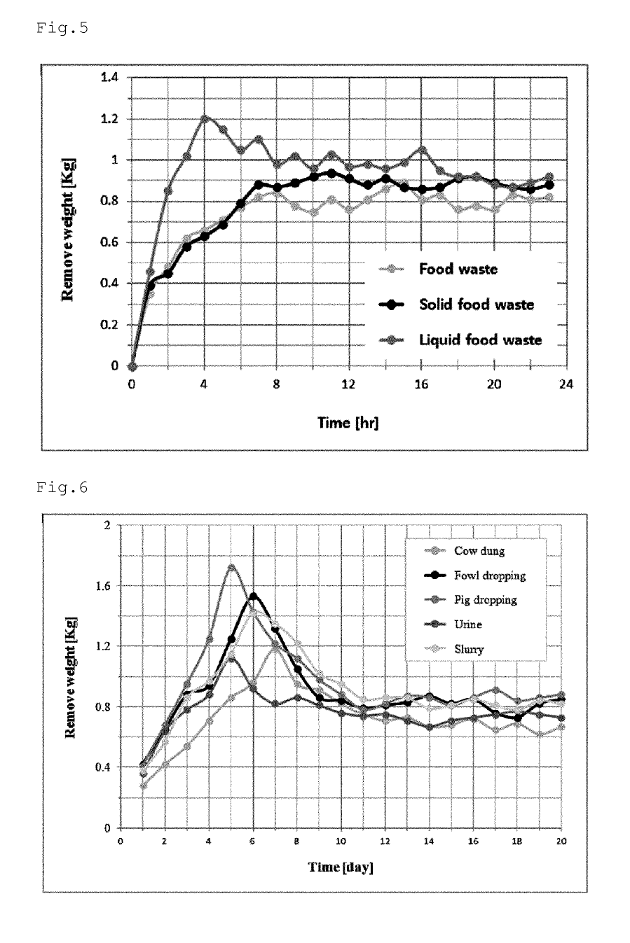

The quantity of food waste treated with a microorganism formulation was determined as follows. First, about 1 kg of food waste was daily added to 10 g of the microorganism formulation (including 0.5 kg of microorganisms plus 9.5 kg of sawdust) each before and after dehydration. The food waste used included 1 kg of original food waste before pulverization and dehydration, or 1 kg of solid food waste or 1 L (1.12 kg) of liquid food waste which were obtained after solid-liquid separation of the original food waste by pulverization and dehydration. As shown in FIG. 5, the treatment efficiency was about 83% on average for the original food waste (including solid and liquid food wastes) before dehydration, and about 88% for the solid food waste after dehydration.

The liquid food waste showed the highest treatment efficiency of about 93%, which is presumably because of the longer processing time, taking more time to destroy the cell membranes of the sold food waste by the heat generated from microorganism-driven exothermic reaction. The analysis for food waste treatment was based on the change in the total weight of the food waste, because the change of weight results from the removal of water from the food waste by the heat generated when microorganisms decompose the organic matters in the food waste.

<Experiment 2>

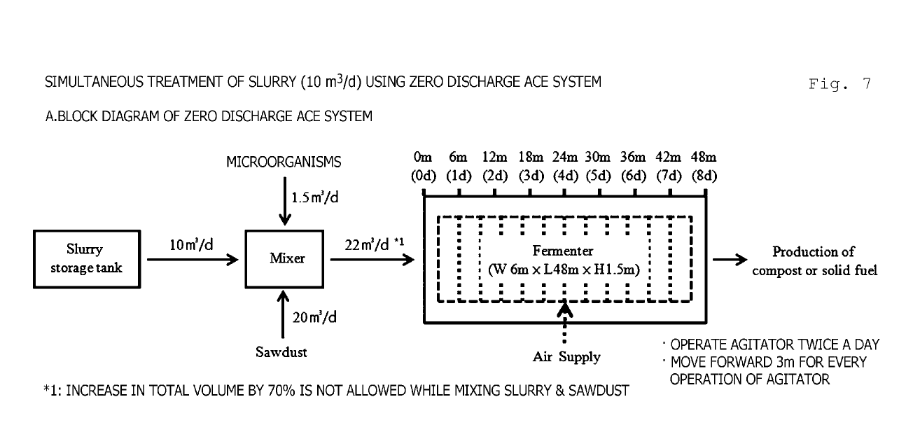

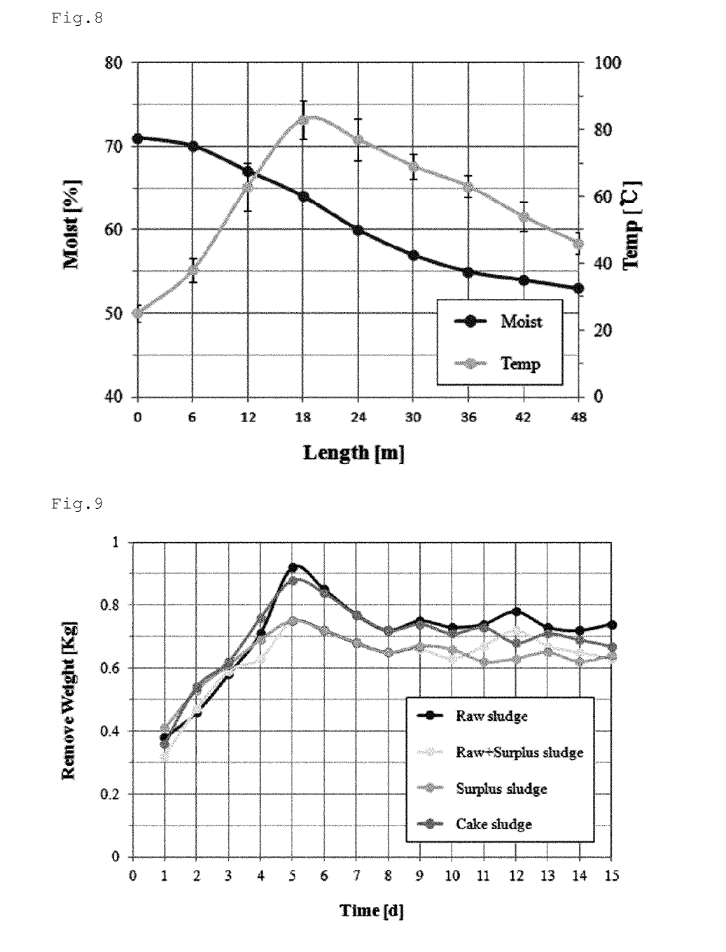

The quantity of livestock excretions treated with a microorganism formulation was determined as follows. First, each 1 kg of cow manure, chicken manure, and pig manure, and each 1 L of pig urine and pig slurry were daily added to 10 kg of the microorganism formulation (including 0.5 kg of microorganisms plus 9.5 kg of sawdust) to evaluate the livestock excretion treatment ability of the fermentation microorganisms through continuous experiments. As shown in FIG. 6, the treatment efficiency was 67%, 85%, 88%, 73%, and 82% for cow manure, chicken manure, pig manure, pig urine, and pig slurry, respectively. In a normal treatment method for pig slurry, the pig slurry is separated into solid and liquid phases, and the solid phase is composted, the liquid phase being purified by activated sludge system or converted into liquid fertilizer. But, as can be seen from this experiment, it is unnecessary to separate the slurry into solid and liquid phases and treat the solid and liquid phases by different methods. The treatment efficiency was no more than 73% for pig urine alone which had a low content of organic matter. However, the treatment efficiency amounted to 82% when 1 L of pig slurry before the solid-liquid separation was daily treated with thermophilic fermentation microorganisms. Further, the treatment efficiency reached 78% in hours in a batch experiment using 3 L of slurry (data not shown). It was therefore revealed that the solid and liquid waste in the slurry can be decomposed at once without being separated from each other. Thus, the liquid phase is required to discard properly according to the standard value, but this method is considered as a zero discharge method for treating slurry without solid-liquid separation and useful for efficient fermentation of organic matters abundant in both solid and liquid phases with microorganisms.

<Experiment 3>

The lab-scaled study of the experiment 2 showed that the slurry of pig excretions can be treated by decomposition without a need for solid-liquid separation. It was determined whether the slurry can be decomposed without solid-liquid separation when the thermophilic fermentation microorganisms were applied to a pilot plant (10 m³/day in scale). The zero discharge ACE system used in the experiment was equipped with an escalator type agitator in a fermentation tank and designed to supply oxygen to aerobic fermentation microorganisms from the bottom of the fermentation tank. The pilot plant zero discharge ACE system was applied to carry out a field test for about 50 days at M swine farm located in Jooksahn myun, Ansung-si, Kyunggi-do, South Korea. First, sawdust and woodchip as a bulking agent, and slurry from M swine farm were mixed with thermophilic fermentation microorganisms, and the mixture was subjected to large-scaled cultivation and activation of microorganisms (pre-culturing). The slurry of M swine farm and sawdust were mixed together at an appropriate mixing ratio, and the mixture was further blended with 5% of activated fermentation microorganisms. The resultant mixture was added into a fermentation tank (6 m×48 m×1.5 m) of FIG. 7 to perform a main culture & continuous test. The biological reaction time of slurry by microorganisms in the fermentation tank was 8 days, and the added amount of slurry was increased step-by-step in the order of 5 m³/day, 8 m³/day, and 10 m³/day to induce the normal operation of the fermentation microorganisms. 10 m³ of slurry, 20 m³ of sawdust, and 1.5 m³ of activated microorganisms were mixed together, and 22 m³ of the mixture was daily added to the fermentation tank. The rotation of the escalator type agitator moved the mixture forward at 6 m/day, so the slurry were treated with microorganisms in the fermentation tank and arrived at the outlet of the fermentation tank in 8 days.

The changes of the moisture content and temperature of the slurry over the biological reaction time (length) of the fermentation tank were measured. As shown in FIG. 8, the mixture in the fermentation tank was gradually warmed up from 60 C on the 2nd day to 82 C on the 4th day. Further, the moisture content of the mixture which was 71% decreased to 64% at a distance of 18 m in the fermentation tank and 53% at the outlet m in distance from the inlet. These results were obtained presumably because the water included in the slurry was evaporated by the exothermic reaction (heat temperature: 63 C or above) of the fermentation microorganisms.

In addition, the concentration change in the slurry over the moving distance in the fermentation tank was measured as follows (See Table 1). First, the BOD and COD values for organic matters were remarkably decreased with an increase in the moving distance in the fermentation tank. The inlet BOD of 25,000 ppm was reduced to the outlet BOD of 2,333 ppm with a removal efficiency of 90%. The removal efficiency of COD was 80%. The removal efficiency for nitrogen components, such as T-N and NH₄-N, was 72% and 74%, respectively, along with the moving distance. With the zero discharge ACE system, carbohydrates, proteins, or liquids included in the pig excretions are decomposed by fermentation microorganisms and converted into intermediary metabolic waste products, which are eventually made into compost or humus. In conclusion, the zero discharge ACE system using thermophilic fermentation microorganisms was capable of decomposing slurry even when applied to a pilot plant 10 m³/day in scale.

TABLE 1
Concentration Change of Slurry by Zero Discharge ACE System

| | | Length (m) | | |
|---|---|---|---|---|
| Item (mg/L) | Slurry (mg/L) | 0 | 24 | 48 |
| BOD₅ | 75,000 ± 3,893 | 25,000 ± 2,076 | 11,350 ± 2,076 | 2,333 ± 523 |
| COD_{cr} | 122,000 ± 4,925 | 76,000 ± 8,230 | 33,450 ± 9,250 | 15,200 ± 4,120 |
| T-N | 9,700 ± 567 | 5,223 ± 362 | 2,241 ± 450 | 1,460 ± 257 |
| NH₄—N | 7,464 ± 512 | 3,575 ± 162 | 1,560 ± 330 | 924 ± 35 |
| NO₂—N | 7 ± 1.2 | 4 ± 2.1 | 35 ± 15 | 58 ± 11 |
| NO₃—N | 195 ± 28 | 105 ± 18 | 147 ± 56 | 165 ± 34 |
| T-P | 1,156 ± 278 | 415 ± 41 | 480 ± 66 | 507 ± 68 |
| PO₄—P | 382 ± 53 | 253 ± 21 | 311 ± 62 | 284 ± 41 |

<Experiment 5>

Table 2 shows the analytical results on the suitability of the final product (humus) of slurry treated by the zero discharge ACE system as compost. As a sample, the final product at distance of 48 m from the inlet in the fermentation tank was collected and analyzed according to “the classification of byproduct fertilizer and livestock composts” in the Fertilizer Control Act. The final product is usually composted (matured) for a long time of about 6 months. But, the humus compost produced by the zero discharge ACE system did not need a long-term composting time, as shown in Table 2. To acquire compost maturity suitable for compost standard, an appropriate C/N ratio is most important. The C/N ratio was slightly higher than the standard value of 40, but it might be lowered after a short composting time and decomposition of the remaining organic matter. The final product had a low electrical conductivity (EC) of 2.95, implying a low TDS value, and thus was considered as suitable compost.

TABLE 2
Analytical Concentration of Compost

| Item (unit) | Standard | | Content | Remarks |
|---|---|---|---|---|
| Total N (%) | — | | 0.79 ± 0.10 | Analysis |
| Total P₂O₅ (%) | — | | 0.64 ± 0.15 | techniques: |
| Total K₂O (%) | — | | 0.95 ± 0.19 | Korea |
| Moisture (%) | 55 ↓ | | 52.5 ± 3.2 | Fertilizer |
| Organic matter (%) | — | | 37.9 ± 2.3 | Quality Test |
| C/N | 40 ↓ | | 48 ± 1.6 | humidification |
| As (mg/kg) | For | 45 ↓ | ND | grade (sobita |
| Cd (mg/kg) | drying | 5 ↓ | ND | test) |
| Hg (mg/kg) | | 2 ↓ | ND | —NH₄: 4 |
| Pb (mg/kg) | | 130 ↓ | ND | —CO₂: 4 |
| Cr (mg/kg) | | 200 ↓ | 8.29 ± 2.1 | |
| Cu (mg/kg) | | 360 ↓ | 110.6 ± 9.6 | |
| Ni (mg/kg) | | 45 ↓ | 7.12 ± 0.5 | |
| Zn (mg/kg) | | 900 ↓ | 172.5 ± 13 | |
| NaCl (mg/kg) | | 1.8 ↓ | 0.97 ± 0.23 | |
| Humidification grade | | 4 ↑ | 4 | |
| pH | | — | 7.5 ± 0.35 | |
| EC (μs/cm) | | — | 2.95 ± 0.56 | |

On the other hand, livestock excretions were treated with fermentation microorganisms for 30 days, and a predetermined amount of humus as a final product was collected and dried out. The powdered sample was analyzed in regard to the lower heating value. As shown in Table 3, the lower heating value was in the range of 2,476 to 2,857 kcal/kg. The heating value of the final product in this experiment did not reach the known heating value of biomass, 3,000 kcal/kg or higher. This is considered because the organic matter included in the livestock excretion is almost completely decomposed by fermentation microorganisms to leave only a small amount of the carbon (organic) components, resulting in a heating value lower than 3,000 kcal/kg. Therefore, the humus obtained as the final product after treatment with fermentation microorganisms has a low content of organic matter and thus can be recycled as high-quality compost (proper C/N ratio, Table 3) or a soil coverage conditioner.

In association with the Green Growth economic policies making the best of biomass in South Korea, the conversion of organic wastes (e.g., livestock excretions, food waste, sewer sludge, etc.) into energy resources, including compost, biogas, solid fuels (e.g., refuse derived fuel (RDF), refuse plastic fuel (RPF), tier derived fuel (TDF), wood chip fuel (WCF), etc.) has recently been encouraged focusing on reduction of dependence of energy on overseas and establishment of green environments. An experiment was carried out to find out a way of enhancing the heating value of the final product of the green transform of biomass, humus, and the usefulness of the humus as a solid fuel. A predetermined amount of livestock excrement was added to the final product, humus. The mixture was subjected to fermentation and drying repeatedly once or twice and then measured in regard to lower heating value. As a result, the increased lower heating value was in the range of 3,230 to 3,707 kcal/kg after a first addition of livestock excrement and 3,690 to 4,463 kcal/kg after a second addition of livestock excrement. This showed that the remaining organic matter of the newly added livestock excretion caused a rise of the heating value.

To solve the problems with the prior art using external energy such as electricity or oils in production of solid fuel from livestock excrements by dehydration and drying and to enhance the heating value of the solid fuel, the present invention produces a solid fuel from eco-environmental livestock excrements by repetitive fermentation and drying without using a heat supplement, such as anthracite, corks, oils, etc., so the solid fuel has a high heating value and prevents a secondary pollution pertaining to incomplete combustion. Further, food wastes containing lots of organic matters are more likely to be used in production of solid fuels. An appropriate amount of food waste is added to the final product, humus, and the procedures were performed in the same manner as described above. As a result, the solid fuel thus obtained had a heating value as high as 4,000 kcal/kg and 4,690 kcal/kg after first and second additions of food waste, respectively.

TABLE 3
Lower Heating Value of Solid Fuel

| | Cow | Chicken | | |
|---|---|---|---|---|
| | manure | manure | Pig manure | Food waste |
| | (kcal/kg) | (kcal/kg) | (kcal/kg) | (kcal/kg) |
| Humus after | 2,476 | 2,786 | 2,857 | 3,524 |
| treatment | | | | |
| First addition of | 3,230 | 3,571 | 3,707 | 4,000 |
| biomass | | | | |
| Second addition of | 3,690 | 4,463 | 4,421 | 4,690 |
| biomass | | | | |

<Experiment 6>

The quantity of sludge treated with a microorganism formulation was measured as follows. First, 1 kg (or 1 L) of concentrated raw sludge, surplus sludge, or dehydrated cake was daily added to 10 kg of the microorganism formulation. As shown in FIG. 9, the treatment efficiency in one day was 75% for raw sludge, 65% for a mixture of raw sludge and surplus sludge, and 70% for dehydrated cake.

In the continuous test for sewer sludge treated with the zero discharge ACE system using a microorganism formulation, the treatment efficiency for the dehydrated cake after digestion reached about 50% in six or more days (data not shown). The treatment efficiency for undigested sludge was high, which was considered because the concentration of organic matter was high enough in the undigested sludge. Most of all, the raw sludge which had a high concentration of organic matter resulted in high treatment efficiency. But, the treatment efficiency was not that high for surplus sludge, which contained organic matters almost completely decomposed by aerobic microorganisms and mostly consisted of dead bodies of microorganisms.

What is claimed is:

1. A method for treating organic waste with a zero discharge ACE system using a microorganism formulation, comprising:
(A) separating a mixed organic waste comprising liquid and solid wastes into liquid and solid wastes, wherein the organic waste comprises food waste, livestock excretion, or sludge; and
(B) conducting a fermentation treatment by adding the liquid waste to use a heat generated from decomposition of organic matter included in the liquid waste in removing water from the liquid waste to control a moisture content during fermentation and decomposition of the solid waste obtained from the solid-liquid separation step (A) using microorganisms or a microorganism formulation, thereby avoiding a need of discarding a discharge water,
wherein the organic waste when comprising livestock excretion (in slurry form) or sludge is not separated into liquid and solid wastes but mixed with the microorganism formulation to undergo fermentation and decomposition.

2. The method according to claim 1, further comprising:
(C) producing a solid fuel from the dewatered solid waste of the fermentation step (B).

3. The method according to claim 1, further comprising:
(F) producing compost from the dewatered solid waste of the fermentation step (B).

4. The method according to claim 1, wherein the solid-liquid separation step (A) comprises:
a storing step (S10) for adding and storing the organic waste in a storage hopper and transferring a naturally occurring liquid waste (L) to a liquid waste storage tank; and
a mixing step (S40) for transferring an isolated solid waste (S) to a mixing tank and adding a microorganism formulation to the solid waste (S), wherein the microorganism formulation comprises a returned microorganism formulation and a new microorganism formulation.

5. The method according to claim 1, wherein the solid-liquid separation step (A) comprises:
a storing step (S10) for adding and storing the organic waste in a storage hopper and transferring a naturally occurring liquid waste (L) to a liquid waste storage tank;
a pulverization and separation step (S20) for transferring the organic waste of the storing step (S10) to a pulverizing separator to blow off light-weighted substances including vinyl with a turbulent flow caused by a wind force and separate the organic waste from heavy-weighted foreign substances including bones or stones; and
a compress dehydration step (S30) for separating the pulverized organic waste of the pulverizing separator into a solid waste (S) and a liquid waste (L) using a dehydrator and then transferring the solid waste (S) to a mixing tank and the liquid waste (L) to a liquid waste storage tank.

6. The method according to claim 4, comprising:
a pre-fermentation step (S50) for transferring a mixture (M) of the microorganism formulation and the solid waste (S) of the mixing step (S40) to a fermentation tank and injecting air into the fermentation tank to accelerate a microorganism fermentation reaction; and
a fermentation step (S60) for removing water from the solid waste (S) of the pre-fermentation step (S50) using a heat generated from decomposition of organic matter by fermentation microorganisms, and adding the liquid waste (L) of the liquid waste storage tank to an appropriate amount of the mixture (M) of the solid waste and the microorganism formulation to decompose the organic matter included in the liquid waste (L) and also to eliminate water from the liquid waste (L) for control of the moisture content of the fermentation microorganisms, thereby reducing the final moisture content of the solid waste (S) to 55% or less.

7. The method according to claim 5, comprising:
a pre-fermentation step (S50) for transferring a mixture (M) of the microorganism formulation and the solid waste (S) of the mixing step (S40) to a fermentation tank and injecting air into the fermentation tank to accelerate a microorganism fermentation reaction; and
a fermentation step (S60) for removing water from the solid waste (S) of the pre-fermentation step (S50) using a heat generated from decomposition of organic matter by fermentation microorganisms, and adding the liquid waste (L) of the liquid waste storage tank to an appropriate amount of the mixture (M) of the solid waste and the microorganism formulation to decompose the organic matter included in the liquid waste (L) and also to eliminate water from the liquid waste (L) for control of the moisture content of the fermentation microorganisms, thereby reducing the final moisture content of the solid waste (S) to 55% or less, wherein when livestock excretion is slurry or sludge, raw sludge is added to an appropriate amount of the mixture (M) of the solid waste and the microorganism formulation.

8. The method according to claim 7, further comprising:
a post-fermentation step (S70) for adding the liquid waste (L) of the liquid waste storage tank to an appropriate amount of the daily mixture (M) at the rear end of the fermentation tank (30) after the fermentation step (S60) to treat a part of the organic matter and water included in the liquid waste (L) using fermentation microorganisms and also to raise the heating value of a solid fuel subsequently produced.

9. The method according to claim 8, further comprising:
a feedback step (S80) for separating woodchip from a humus (H) of the organic waste of the post-fermentation step (S70) with a drum screen separator (50) and feeding the isolated woodchip, sawdust or the humus of the organic waste at a ratio of about 30 wt % of the mixture (M) back to the mixing tank for further circulation, wherein the humus comprises a returned microorganism formulation (OR).

10. The method according to claim 9, comprising:
a composting step for adequately composting (or fully maturing) the remaining humus (H) of the feedback step (S80) to produce compost;
a pulverization step (S90) for pulverizing the remaining humus (H) of the feedback step (S80) into particles having a size of 5 mm or smaller using a roll crusher (70) to produce a solid fuel having a uniform heating value from the remaining humus (H);
a drying step (S100) for drying the crushed humus (H) of the pulverization step (S90) to have a moisture content of about 20% using a hot air boiler at 200 C or below, thereby removing a remainder of water from the crushed humus (H), wherein the drying step is performed using a hot air boiler in a temperature range not allowing volatilization of the organic matter;
a step for feeding a foul odor gas including ammonia nitrogen generated in the drying step into the fermentation tank to eliminate a foul odor using microorganisms;
a step for feeding a waste heat generated in the drying step into the fermentation tank to accelerate an exothermic reaction (including a kind of thermophilic fermentation reaction) of the microorganisms and remove water from the organic waste;
a press molding step (S110) for pressing the humus (H) into a solid fuel pellet to produce a solid fuel (P) from the humus (H) of the drying step (S100); and
a packaging step for transferring a part of the solid fuel (P) produced in the press-molding step (S110) to the hot air boiler as a source of heat and the remainder of the solid fuel (P) to a packaging unit to form a final product.

11. The method according to claim 10, further comprising:
an energy-producing step (D) for generating electrical energy from the waste heat generated in the drying step (S100) using thermoelectric elements.

12. The method according to claim 10, further comprising:
an energy-producing step (D) for rotating a turbine of a combined heat-and-power generator using a high-speed steam flow produced by the waste heat of the drying step (S100) and converting mechanical energy into electrical energy.

13. The method according to claim 1, wherein the organic waste comprises food waste alone or in combination with livestock excretion or sludge of sewer water or waste water; or livestock excretion alone or in combination with food waste or sludge of sewer water or waste water.

14. An apparatus for treating organic waste and producing compost and solid fuel by a zero discharge ACE system using a microorganism formulation, comprising:
a storage hopper (2) for storing the organic waste, wherein the storage hopper (2) comprises a connection pipe (24) provided on the one side of the bottom end thereof and connected to a liquid waste storage tank (4) to discharge a liquid waste (L), and a discharge pipe 21 provided on the bottom thereof and used for discharging a solid waste (S);
a mixing tank (10) for mixing the solid waste (S) received from the storage hopper (2) with a novel microorganism formulation or returned humus and woodchip;
a fermentation tank (30) comprising a cylindrical main body (31) for receiving a mixture (M) of the mixing tank (10) and having a screw shaft (32) for continuously stirring the mixture (M) and transferring the mixture (M) from inlet to outlet, an air feeding device (60) for injecting air into the main body (31), an air discharging device (80) for outwardly discharging internally occurring water vapor, and a liquid waste feeding device (67) for injecting the liquid waste (L) into the main body (31); and
a drum screen separator (50) for separating woodchip, sawdust, or humus (H) from the mixture discharged from the fermentation tank (30) using a rotating screen, and feeding a part of the humus (H) back into the mixing tank (10).

15. The apparatus according to claim 14, further comprising:
a pulverizing separator (6) having a blower (62) and a screen drum (64) for removing foreign substances from the organic waste received from the storage hopper (2) when the organic waste comprises food waste alone or in combination with livestock excretion; and
a dehydrator (8) for compressing and separating the organic waste received from the pulverizing separator (6) into a solid waste (S) and a liquid waste (L), and transferring the liquid waste (L) to the liquid waste storage tank (2).

16. The apparatus according to claim 14, wherein for producing a solid fuel from the separated humus (H) of the drum screen separator (50), the apparatus comprises:
a roll crusher (70) for crushing the humus (H);
a hot air boiler (120) for drying the crushed humus (H) at 200 C or below to remove a remainder of water from the crushed humus (H), wherein the hot air boiler is operated in a temperature range not allowing volatilization of organic matter;
a press molding unit for producing a solid fuel (P) from the dried humus; and
a packaging unit for packaging the solid fuel into a final product.

17. The apparatus according to claim 16, further comprising:
a generator (160) comprising a plurality of thermoelectric elements for recycling a waste heat generated from the hot air boiler (120) and generating electrical energy.

18. The apparatus according to claim 16, further comprising:
a generator for using a high-speed steam flow generated from the hot air boiler (120) by combustion of the solid fuel to rotate a turbine of a combined heat-and-power generator and convert mechanical energy into electrical energy.
